(19) United States
(12) Patent Application Publication
(10) Pub. No.: US 2025/0110254 A1
(43) Pub. Date: Apr. 3, 2025

(54) PREDICTING DEPOSITIONAL ENVIRONMENTS USING WIRELINE LOGS, CORE INTERPRETATION, AND MACHINE LEARNING

(71) Applicant: Saudi Arabian Oil Company, Dhahran (SA)

(72) Inventors: Saleh M. Badawood, Dhahran (SA); Miatham Adnan Al Saleh, Dhahran (SA); Ali Hassan Alabdrabalnabi, Al Qatif (SA)

(21) Appl. No.: 18/477,171

(22) Filed: Sep. 28, 2023

(51) Int. Cl. G01V 99/00; G06F 30/27

(52) U.S. Cl. CPC G01V 20/00; G06F 30/27

(57) ABSTRACT

Systems and methods include a computer-implemented method for predicting depositional environments in regional geology using wireline logs, core interpretation, and machine learning algorithms. Data preprocessing is performed on core data and wireline data received from wells that have been drilled to generate pre-processed core and wireline data. The pre-processed core and wireline data are split into a training dataset and at least one testing dataset. A model is generated using the pre-processed core and wireline data, and models relationships between core-based depositional settings and wireline logs for the wells. Feature engineering is performed on the pre-processed core and wireline data to identify significant features that contribute to the model. The model is trained using the training dataset and by weighting the significant features. The model is evaluated using machine learning on the testing dataset. Depositional settings are predicted using the model and results of the evaluating.

### TECHNICAL FIELD

The present disclosure applies to depositional facies prediction and machine learning.

### BACKGROUND

Depositional maps include one or more depositional environments (or depositional settings) that can provide regional context during exploration of reservoirs. The maps represent geographical areas corresponding to large amounts of data. Traditional techniques use porosity-permeability relationships to provide insights into rock properties, lithological variations, and reservoir quality. The relationships may not be sufficient to directly identify and differentiate depositional facies, resulting in depositional environments with reduced resolution and accuracy.

### SUMMARY

The present disclosure describes techniques that can be used to predict depositional environments in regional geology using wireline logs, core interpretation, and machine learning algorithms. The techniques involve selecting appropriate wireline logs, performing petrophysical analysis on the logs, identifying depositional sedimentary facies from core data, training machine learning algorithms, and validating the results. The accuracy of the predictions can be improved by calibrating the petrophysical analysis with core data. The techniques can be applied to a wide range of reservoir types and lithologies, saving time and costs compared to existing techniques.

In some implementations, a computer-implemented method includes the following. Data preprocessing is performed on core data and wireline data received from wells that have been drilled. The data processing generates pre-processed core and wireline data. The pre-processed core and wireline data are split into a training dataset and at least one testing dataset. A model is generated using the pre-processed core and wireline data. The model learns relationships between core-based depositional settings and wireline logs for the wells. Feature engineering is performed on the pre-processed core and wireline data to identify significant features of the pre-processed core and wireline data that contribute to the model. The model is trained using the training dataset and by weighting the significant features. The model is evaluated using machine learning on the testing dataset, depositional settings are predicted using the model and results of the evaluating.

The previously described implementation is implementable using a computer-implemented method; a non-transitory, computer-readable medium storing computer-readable instructions to perform the computer-implemented method; and a computer-implemented system including a computer memory interoperably coupled with a hardware processor configured to perform the computer-implemented method, with the instructions stored on the non-transitory, computer-readable medium.

The details of one or more implementations of the subject matter of this specification are set forth in the Detailed Description, the accompanying drawings, and the claims. Other embodiments, aspects, and advantages of the subject matter will become apparent from the Detailed Description, the claims, and the accompanying drawings.

### DESCRIPTION OF DRAWINGS

FIG. 1 is flow diagram showing an example workflow for developing, training, and evaluating a prediction model, according to some implementations of the present disclosure.

FIG. 2 is a graph showing example of predictor weights for different predictors, according to some implementations of the present disclosure.

FIG. 3 is a graph showing example actual facies versus model predicted facies, according to some implementations of the present disclosure.

FIGS. 4A and 4B are graphs collectively depicting an example of a well log showing model prediction, training and validation results, according to some implementations of the present disclosure.

FIG. 5 is a flowchart of an example of a method for predicting depositional environments, according to some implementations of the present disclosure.

FIG. 6 illustrates hydrocarbon production operations that include both one or more field operations and one or more computational operations, which exchange information and control exploration for the production of hydrocarbons, according to some implementations of the present disclosure.

Like reference numbers and designations in the various drawings indicate like elements.

### DETAILED DESCRIPTION

The following detailed description describes techniques for predicting depositional environments using wireline logs, core interpretation, and machine learning (ML). The depositional environments include facies, where a facie is a geological unit (e.g., rock) having characteristics different from other geological units in the vicinity. The characteristics include, for example, mineralogy and sedimentary sources, fossil content, sedimentary structures, and texture. The techniques for predicting depositional environments can include, for example, training a machine learning model to identify depositional environments based on wireline logs. This can solve the challenge of establishing a relationship between depositional environments and wireline data. Various modifications, alterations, and permutations of the disclosed implementations can be made and will be readily apparent to those of ordinary skill in the art. The general principles defined may be applied to other implementations and applications, without departing from the scope of the disclosure. In some instances, details unnecessary to obtain an understanding of the described subject matter may be omitted so as not to obscure one or more described implementations with unnecessary detail, as such details are within the skill of one of ordinary skill in the art. The present disclosure is not intended to be limited to the described or illustrated implementations, but to be accorded the widest scope consistent with the described principles and embodiments.

In some implementations, a workflow for predicting depositional environments using wireline logs can be correlated with core interpretation and machine learning algorithms. The workflow can involve the following steps, for example.

Firstly, appropriate wireline logs can be selected based on their sensitivity to lithology and fluid content and the depth range of interest. Commonly used logs can include gamma-ray, resistivity, density, and sonic logs.

Available wireline logs can be evaluated to determine their importance for predicting output (e.g., facies). Studying the nature or patterns in wireline logs can lead to a determination that some logs are designed to detect variations in lithology or fluid type. An example is a gamma ray log, which can be used to detect the radioactivity of clay minerals in the rock. Gamma ray logs are typically used to identify shale rock intervals from sandstone intervals. Resistivity logs are designed to detect variations in rock conductivity as a function of fluid content and porosity distribution. After understanding the relationships between features extracted from these logs and predicted facies, logs that do not have a correlation with facies for prediction can be removed from consideration (for predicting facies), since their impact on the model is less significant, if not redundant. In some examples, the features are weighted (e.g., predictor weight) according to an ability of the feature or changes in the feature to predict facies. The higher the ability of the feature or changes in the feature to predict facies, the higher the weight. The lower the ability of the feature or changes in the feature to predict facies, the lower the weight. In examples, the weights assigned to the features is relative based on the weights applied to known features.

Secondly, petrophysical analysis can be performed on the wireline logs to calculate parameters that include, but are not limited to, porosity, water saturation, and permeability. The accuracy of the petrophysical analysis can be improved by correlating the analysis with core data.

Thirdly, sedimentary facies can be identified from the core data using visual or image analysis techniques. These facies can then be correlated with the wireline log data to create a facies log, which can be used to train machine learning algorithms to predict depositional environments. Structured core-based interpretation of depositional environments can be done by a professional sedimentologist. Core-based interpreted facies can be correlated to the wireline logs using a model generated through machine learning.

Fourthly, machine learning algorithms can be trained to predict depositional environments using the wireline log data. Algorithms that are used can include random forests, support vector machines, and artificial neural networks, among others. The machine learning algorithms can be trained using the facies log as the target variable and the petrophysical properties of the wireline logs as the input variables.

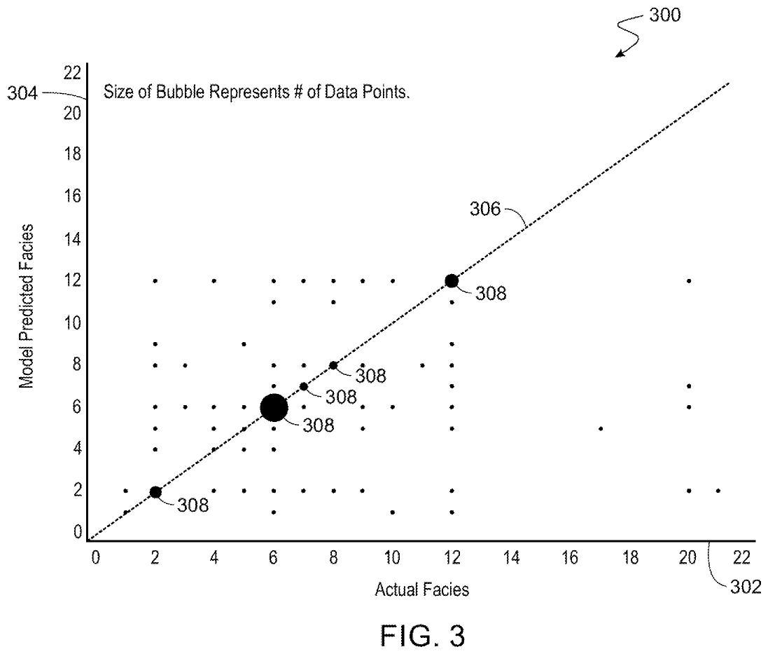

Finally, the results can be validated using independent data by comparing the predicted facies with actual facies from core data. The accuracy of the predictions can be evaluated using statistical metrics such as confusion matrices and accuracy scores. Example validation results are shown in FIG. 3.

Models can be established to model a relationship between core-correlated depositional environment facies and wireline logs. Existing depositional environments can be interpreted using lithological facies association and sequence stratigraphy in wireline logs. This provides the capability to predict depositional facies in wireline logs if trained on a representative sample of core interpreted depositional facies.

The techniques described herein can be implemented to realize one or more of the following advantages. By building models to predict depositional environments using wireline logs, automated computer-implemented actions are executed to improve the accuracy of identifying depositional facies, e.g., where certain reservoir properties are likely to be encountered. Using these techniques can reduce the number of cores needing to be acquired in non-reservoir intervals.

The techniques of the present disclosure solve several technical problems in the field of petroleum industry geology. For example, conventional sedimentary facies analysis typically uses core data to predict depositional environments. However, this type of approach can be costly and time-consuming, and the number of available cores is typically limited compared to logged wells. The techniques of the present disclosure increase available data by providing an alternative approach to using wireline logs, such as by using petrophysical methods to provide information about reservoir lithology and fluid content. This approach is less costly and less time-consuming than approaches using core data and can be applied to a wide range of reservoir types and lithologies.

Further, the techniques of the present disclosure combine wireline logs with core data and machine learning algorithms to improve the accuracy of predicting depositional environments. Machine learning algorithms are used to learn patterns and relationships between petrophysical properties of wireline logs and sedimentary facies from core data. The use of machine learning models leads to better predictions of depositional environments. The accuracy of the predictions can be evaluated using statistical metrics such as confusion matrices, receiver operating characteristic curves, and accuracy scores.

The techniques of the present disclosure can enable the enhancement of gross depositional map resolution and accuracy by adding additional data points. This can lead to the ability to create three-dimensional (3D) gross depositional models instead of two-dimensional (2D) maps. Overall, the techniques of the present disclosure can solve technical problems related to cost, time, and accuracy associated with predicting depositional environments in petroleum industry geology.

Other benefits and advantages associated with the present techniques can include, for example, improving de-risking of play concepts, enhanced resolution of gross depositional environments (GDEs) and composite common risk segment (CCRS) maps, transitions from 2D to 3D GDE models, and generating correlated seismic attribute facies models. Core interpretations of the depositional environment can serve as the main input for GDE mapping. Facies of the depositional environment can be chosen as the primary target of prediction.

Predicted depositional environments settings output by a trained model can provide additional data points in un-cored wells and logged wells. Outputs of the trained model can be shared with exploration teams, enabling the teams to plan better for data acquisition (e.g., cores, side well core plugs, source rocks samples), in addition to generating 3D seismic facies models after correlation with seismic attributes.

Real-time predictions can be made while drilling wells. Prediction accuracy can be improved with additional logs. This can provide decision-makers with depositional environment prediction from wireline logs before core description. Additionally, the present techniques can be utilized to identify the optimum reservoir intervals to test, for example identifying targeted Aeolian dunes facies within your logged intervals. Workflows can be continuously improved for accuracy.

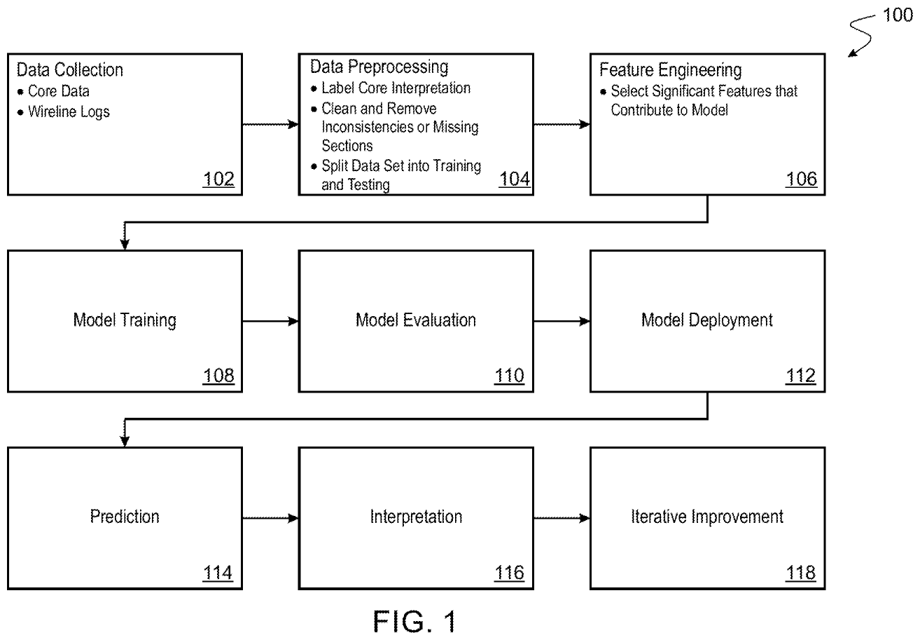

FIG. 1 is flow diagram showing an example workflow 100 for developing, training, and evaluating a prediction model, according to some implementations of the present disclosure.

At 102, data collection of core data and wireline logs occurs. In examples, data is collected from wells with cores in a selected stratigraphic unit that overlaps with wireline logged section of wells in a field. In some examples, data associated with wells covered by wireline logs in the selected stratigraphic unit is also captured to be utilized in the prediction phase (e.g., input to a trained model for prediction of facies). Moreover, wells are selected from an entire geographical area of interest, to ensure the capture of various facies in the depositional environment of the selected stratigraphic unit.

At 104, data preprocessing occurs. The data is typically stored in reports and described in an unstructured format and include no labels. The data includes, for example, unstructured core descriptions. The interpretation of these unstructured descriptions can include labeling the depositional settings of the cores and defining the paleogeographic and environment of deposition of the cores, such as when the data is retrieved. In examples, missing data (e.g., missing descriptions of cores) is filled in by interpreting a borehole image log. One way to remove inconsistencies is by validating the core interpretation with other interpreted cores and assessing the correlation in interpreted facies. In examples, by correlating the wireline logs and core data at one or more depths of a well, data along depths of the wireline logs are associated with at least one facie as defined by the core.

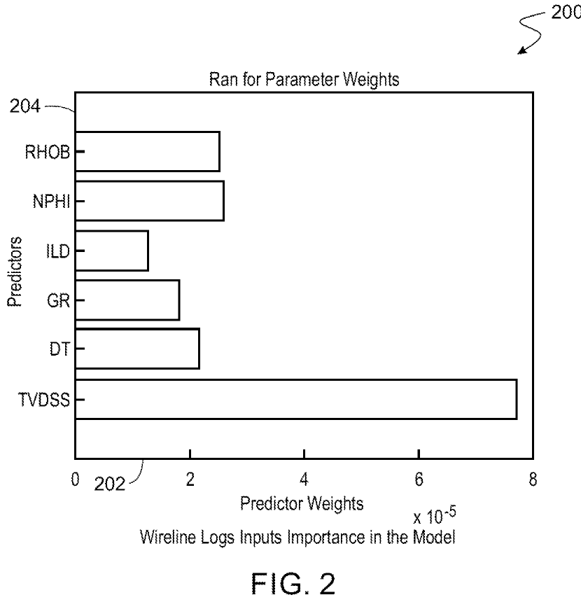

At 106, feature engineering is performed, in which significant features contributing to the predictive model are selected. Feature engineering can be defined as using machine learning with data used to train the predictive model to identify respective contributions of different features for making predictions of depositional environments using the model. Based on, for example, principal components analysis, features of wireline logs that are identified as relevant to the predictive model are extracted for training the predictive machine learning model. In some examples, relevant or significant features are manually identified in the wireline logs or core data. Additionally, in examples, feature engineering identifies the patterns, relationships, or other behaviors in existing wireline logs and core data, transforms the existing data based on these relationships, and then quantifies the importance (e.g., predictor weights) of these relationships so that the predictive model is trained using the most important relationships. In examples, insignificant relationships, those with a relatively lower quantified importance, are excluded from use in training. For example, the if importance of a feature fails to satisfy a predetermined threshold, the feature is excluded or removed from training or testing datasets. Additionally, after training the model (108) in multiple machine learning algorithms features are re-examined based on their weights importance to the predictive model at hand and can be added or removed from the final model. Predictor weights can be determined by analyzing the correlation of values in historical logs with respect to depositional environments. Examples of predictor weights of different parameters (e.g., significant features) regarding their importance of being predictors in the model are described with reference to FIG. 2. Significant features can also be selected in other ways without using predictor weights, such as by using an industry standard list of features.

At 108, the model is trained. The selected input features along with the targeted prediction column is input into machine learning software to build the predictive model using multiple machine learning algorithms. The training can include determining, over time, which features are best predictors of depositional environments. In examples, at least one machine learning model is trained to predict depositional environments of a well using as input at least one feature extracted from wireline logs associated with the well.

At 110, the model is evaluated, using model performance metrics that are generated from the software. In the development of the techniques of the present disclosure, multiple models were generated, and the best fit model was identified based on the model performance metrics of the models. Some implementations can use a predictive model in which metrics are associated with percentages of accuracy, error, precision rate, and false positive rate. Higher-performing models generally have a high accuracy score, low error percentage, high precision rate, and low false positive rate. Afterward, a second round of testing of the models can be performed on a secondary blind test data set.

At 112, the model is deployed. For example, upon selection of the best fit model based on the metrics and performance on the secondary blind test, the model can be shared with the team for use (e.g., in production). Upon deployment, the trained model is executed with unseen log data as input. For example, data associated with wells covered by wireline logs in the selected stratigraphic unit is utilized in the prediction phase (e.g., input to a trained model for prediction of facies).

At 114, predictions are made using the model. In examples, the model is used to predict depositional facies in un-cored wells. This provides geologists who build gross depositional environment maps and models with valuable additional data points in un-cored areas. The model can provide the depositional environment facies depending on the presence of the used logs as input features to build the previous model in these wells.

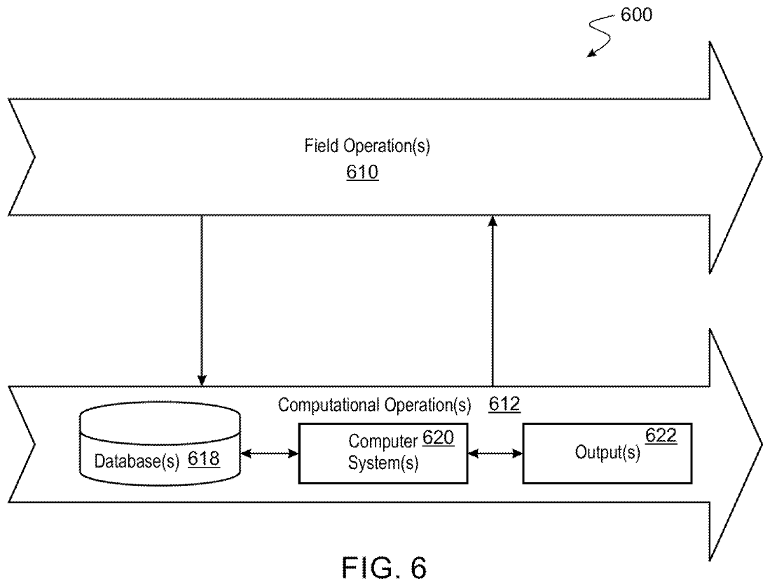

At 116, the predictions are interpreted. The predicted facies across the stratigraphic interval can be plotted as pie charts on maps to designate the most dominant facies within the stratigraphic intervals in each well. Then, the dominant facies can be used to map the gross depositional settings in this stratigraphic interval. Thus, a gross depositional map of the stratigraphic unit across the area of interest can be generated. In examples, the predictions are used to guide field operations, computational operations, or any combination thereof. The field operations and computational operations are the same as or substantially similar to the field operations 610 and computational operations 612 described with respect to FIG. 6.

At 118, the model is iteratively improved. As new cores are labeled or acquired through newly drilled wells, this process is revisited and the model regenerated to improve the predictive ability of the model.

FIG. 2 is a graph 200 showing example of predictor weights 202 for different predictors 204, according to some implementations of the present disclosure. The importance of each predictor is based on depositional environment predictions using wireline logs and machine learning model input features importance. In machine learning workflows, feature importance is a measure of the impact of each input feature to the predictive model. It is done by calculating the effect on the accuracy of the model when each feature is removed. A hierarchy can be established that places a feature (or a group of deterministic features, when combined) higher in the hierarchy when the feature (or group) is a better predictor of depositional environments. The predictors 204 include bulk density (RHOB), neutron porosity (NPHI), deep induction resistivity (ILD), gamma ray (GR), and Delta-T (DT) logs, and true vertical depth subsea (TVDSS). These predictors are essential inputs used in predicting depositional facies in the ML model.

Serving as a vertical positioning tool, the TVDSS log provides the vertical depth information of the subsurface formations. The TVDSS log can help in identifying the specific depth intervals associated with different depositional facies. By considering the TVDSS log as an input, the ML model can learn the vertical distribution of facies and incorporate depth-related patterns into its predictions.

Lithology-related logs, including RHOB, NPHI, and ILD, are logs that are commonly used to determine the lithology or composition of the rocks. Each of the depositional facies typically exhibits specific lithological properties, such as density, porosity, and resistivity. By including these logs as inputs, the ML model can learn the relationships between lithology and depositional facies and make predictions based on the derived lithological characteristics.

For geological features, the GR log measures the natural radioactivity emitted by the formation. The GR log helps identify different geological features, such as shale, sandstone, or carbonate intervals. These features are often associated with specific depositional facies. Incorporating the GR log as an input allows the ML model to capture the relationships between the gamma ray responses and facies variations.

For pore fluid properties, the DT log measures the travel time of acoustic waves through the rock formation, which is influenced by the properties of the pore fluid. Different depositional facies may exhibit variations in fluid content, salinity, or other fluid-related characteristics. Including the DT log as an input enables the ML model to learn the connections between depositional facies and fluid properties, aiding in predicting facies based on acoustic responses.

By combining these logs as input features, an ML model can leverage the respective contributions of the logs to learn the complex relationships between various well log responses and depositional facies. This enables the model to make predictions on the facies distribution in un-cored intervals, or in areas where facies information is limited.

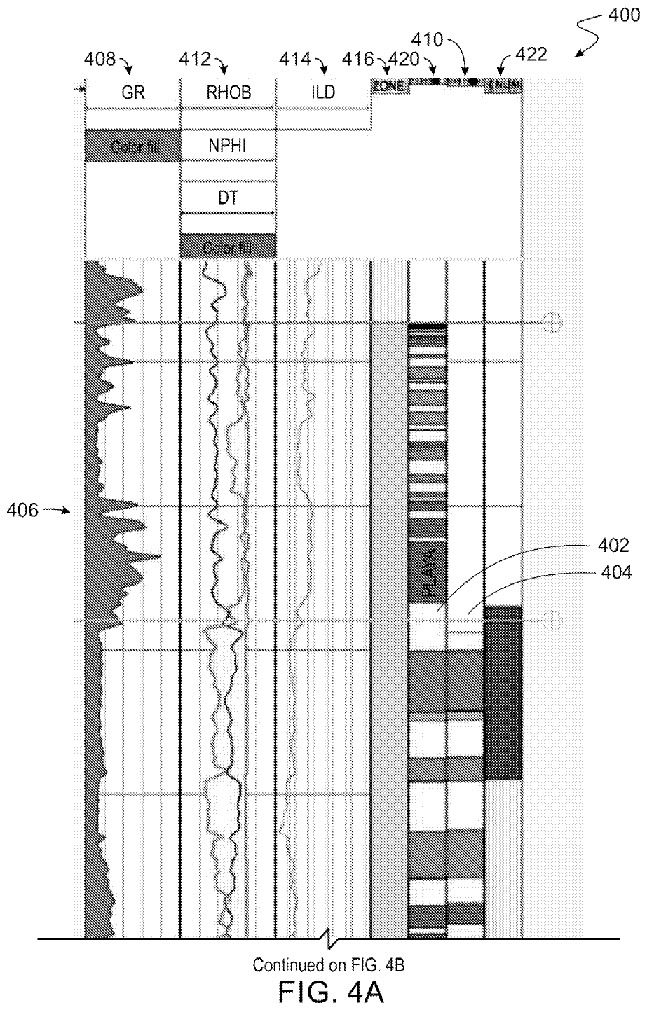

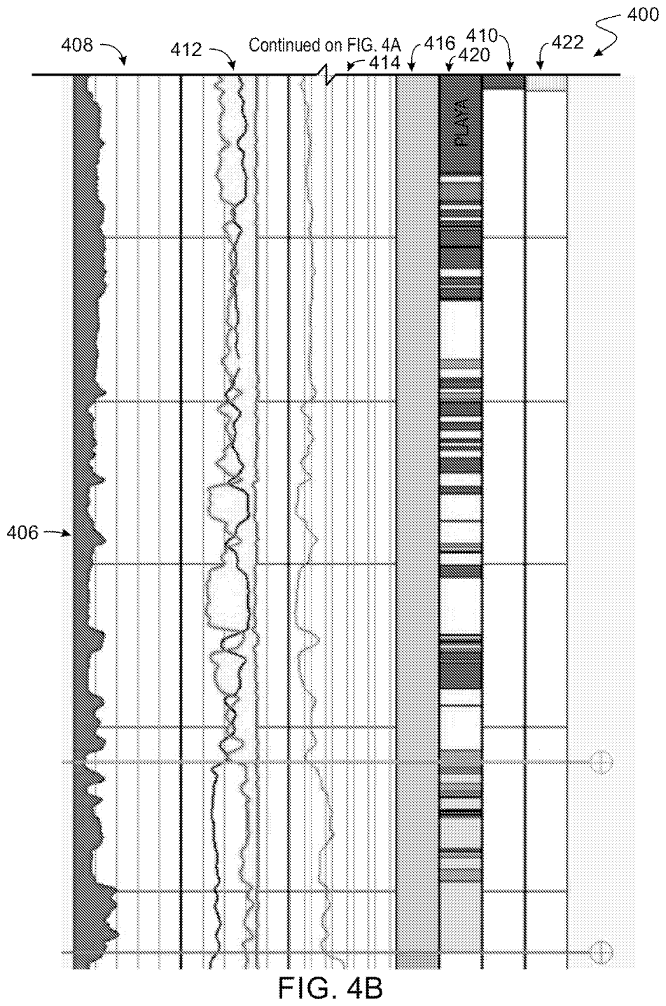

In an example, training a predictive model that outputs make depositional environment predictions using wireline logs and machine learning includes the following. The dataset was split into three parts: a training set of 3,617 feet of cores data (42%); a first testing set #1 of 1,406 feet of cores data (28%); and a second testing set #2 of 1,674 feet of cores data (30%). Creation of the model included establishing the relative importance of wireline logs in prediction (e.g., establishing predictor weights). Nine different ML models for predicting depositional environments were created. The model that had the best performance metrics was selected for its greater accuracy and lesser percentage of error. Examples of depositional environment predictions are shown in FIGS. 4A and 4B, where the model is used to predict facies. In this example, the model is predicting the facies in numerical values that were designed initially. The numerical values are represented graphically in FIGS. 4A and 4B in track model prediction 402.

TABLE 1
Model Accuracies

| | Training Set | Training | Testing Set | Testing |
|---|---|---|---|---|
| | Accuracy | Set | Accuracy | Set |
| Model | (%) | Error (%) | (%) | Error (%) |
| LogisticR | 93.64 | 6.36 | 80.4 | 19.6 |
| LDA | 45.81 | 54.19 | 45.17 | 54.83 |
| ANN | 11.37 | 88.63 | 12.18 | 87.82 |
| RegTree | 95.63 | 4.37 | 83.97 | 16.03 |
| KNN | 100 | 0 | 91.04 | 8.96 |
| SVM | 97.92 | 2.08 | 89.74 | 10.26 |
| RanFor | 100 | 0 | 91.6 | 8.4 |
| NaiveBayes | 78.06 | 21.94 | 70.52 | 29.48 |

FIG. 3 is a graph 300 showing an example of actual facies 302 versus model predicted facies 304, according to some implementations of the present disclosure. Results of a second blind indicated that the RanFor model has high accuracy and a reasonable percentage of error, with an accuracy (%) of 93.1 and an error (%) of 6.9. Data points 308 in the graph 300 are plotted relative to an asymptote 306, with a size of a bubble representing multiple data points identifying the number of data points 308 at that coordinate in the graph.

FIGS. 4A and 4B are graphs collectively depicting an example of a well log 400 showing different tracks and model prediction, training and validation results, according to some implementations of the present disclosure. Model prediction 402 of facies and training and validation data 404 are displayed relative to a depth 406. In this example, the model was run on all wells covered by the study tops and wireline logs for 532 wells and 11,874 feet of coverage. A facies track 410 shows validation data 404, includes depositional environments interpreted by a sedimentologist. The model prediction 402 track displays model predictions of depositional environments. Track 408 shows gamma ray log. Track 412 shows sonic (DT), bulk density (RHOB), and neutron porosity (NPHI) logs. Track 414 shows deep induction logs (ILD). Track 416 shows zones based on the well tops. Track 420 shows ML-predicted facies. Track 422 displays the cores available in this well.

This well log 400 shows data corresponding to a single well. The model prediction makes a prediction of depositional settings for the entire track, and thus provides additional data/information where the sedimentologist interpretation is limited by the core coverage. Thus, the ML prediction track is available for most of the well.

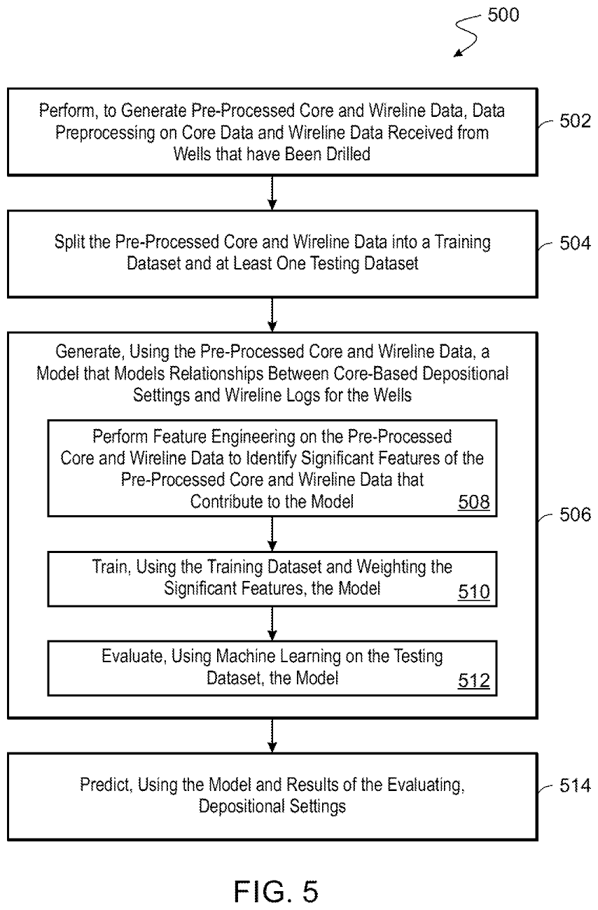

FIG. 5 is a flowchart of an example of a method 500 for predicting depositional environments, according to some implementations of the present disclosure. For clarity of presentation, the description that follows generally describes method 500 in the context of the other figures in this description. However, it will be understood that method 500 can be performed, for example, by any suitable system, environment, software, and hardware, or a combination of systems, environments, software, and hardware, as appropriate. In some implementations, various steps of method 500 can be run in parallel, in combination, in loops, or in any order.

At 502, data preprocessing is performed on core data and wireline data received from wells that have been drilled. The data processing generates pre-processed core and wireline data. In some implementations, performing the data while preprocessing core data and wireline data includes, labeling core interpretations, cleaning the core data and wireline data, and removing inconsistencies and resolving missing data. Cleaning the data can include fixing or removing incorrect, corrupted, incorrectly-formatted, duplicate, or incomplete data. For example, missing data can be determined by interpolating values from a borehole image log. Inconsistent data can be identified when certain values are out of range or don't make sense in relation to other values. From 502, method 500 proceeds to 504.

At 504, the pre-processed core and wireline data are split into a training dataset and at least one testing dataset. In some implementations, splitting the pre-processed core and wireline data into a training dataset and at least one testing dataset includes splitting the dataset into a training set of 42% of cores data, a first testing set of 28% of the cores data, and a second testing set of 30% of the cores data. Other percentages are possible based on the needs of training and may be influenced and changed over time based on the results obtained. From 504, method 500 proceeds to 506.

At 506, a model is generated using the pre-processed core and wireline data. In some examples, the pre-processing is the same as or similar to preprocessing described with respect to block 104 of FIG. 1. The model learns the relationships between core-based depositional environments and wireline logs for the wells. In some implementations, step 506 includes steps 508 to 512.

At 508, feature engineering is performed on the pre-processed core and wireline data to identify significant features of the pre-processed core and wireline data that contribute to the model. In some examples, the feature engineering is the same as or similar to feature engineering described with respect to block 106 of FIG. 1. For example, performing feature engineering on the pre-processed core and wireline data to identify significant features can include using machine learning with the model to identify respective contributions of different features for making predictions of depositional environments using the model. In some implementations, the respective contributions can be represented as predictor weights that weight the significant features. Predictor weights can be implemented as percentages or scores, and may be based on historical results. From 508, method 500 proceeds to 510.

At 510, the model is trained using the training dataset and by weighting the significant features. In some examples, the training is the same as or similar to training described with respect to block 108 of FIG. 1. The machine learning tool goes through a sensitivity analysis of tracking how the accuracy of the model is affected by the removal of the input features. The sensitivity analysis can use a pre-determined sequence of measuring the effects of the presence (and non-presence) of each feature in order to isolate each feature's affect. Then the tool provides the importance weight of each feature in predicting the validation data. From 510, method 500 proceeds to 512.

At 512, the model is evaluated using machine learning on the testing dataset. After building the machine learning model using multiple algorithms, the model is tested on predicting the facies in the pre-split testing set 1. In some examples, the evaluation is the same as or similar to evaluation described with respect to block 110 of FIG. 1. The accuracy of the model is assessed based on performance metrics in training and testing sets. From 512 (and 506), method 500 proceeds to 514.

At 514, depositional environments are predicted using the model and results of the evaluating. In some examples, the prediction is the same as or similar to the prediction described with respect to block 114 of FIG. 1. The best performing model can be selected based on performance metrics (e.g., accuracy, error rates, precision rates, and false positive rate percentages). In examples, the best performing model is based on a comparison of respective performance metrics associated with predictions output by multiple models. After the selected model is evaluated, the selected model can be approved for use in making predictions if the predictions made during production satisfy at least one predetermined threshold. Then, wells that have coverage of wireline logs can be used as input features for the model and used to predict depositional facies. After 514, method 500 can stop.

In some implementations, method 500 can include further generating, using the predicted depositional environments, and for display to a user, a depth chart showing model prediction and validation results. For example, the depth chart can be the depth chart 400 described with reference to FIGS. 4A and 4B and can include, for each depth of a well, ML-predicted facies. Predicted facies can be generated for active wells that have acquired wireline logs, to enable exploration teams to improve the selection of data acquisition intervals such as sampling, testing, and perforation intervals. Information for predicted depositional environments can also be used to determine pressure points and side well cores. Data acquisition intervals can be set at specific depth intervals (e.g., measured in meters), which may be variable in certain parts of a well.

FIG. 6 illustrates hydrocarbon production operations 600, that include both one or more field operations 610 and one or more computational operations 612, which exchange information and control exploration for the production of hydrocarbons. In some implementations, outputs of techniques of the present disclosure can be performed before, during, or in combination with the hydrocarbon production operations 600, specifically, for example, either as field operations 610 or computational operations 612, or both.

Examples of field operations 610 include forming/drilling a wellbore, hydraulic fracturing, producing through the wellbore, and injecting fluids (such as water) through the wellbore, to name a few. In some implementations, methods of the present disclosure can trigger or control the field operations 610. For example, the methods of the present disclosure can generate data from hardware/software including sensors and physical data gathering equipment (e.g., seismic sensors, well logging tools, flow meters, and temperature and pressure sensors). The methods of the present disclosure can include transmitting the data from the hardware/software to the field operations 610 and responsively triggering the field operations 610 including, for example, generating plans and signals that provide feedback to and control physical components of the field operations 610. Alternatively, or in addition, the field operations 610 can trigger the methods of the present disclosure. For example, implementing physical components (including, for example, hardware, such as sensors) deployed in the field operations 610 can generate plans and signals that can be provided as input or feedback (or both) to the methods of the present disclosure.

Examples of computational operations 612 include one or more computer systems 620 that include one or more processors and computer-readable media (e.g., non-transitory computer-readable media) operatively coupled to the one or more processors to execute computer operations to perform the methods of the present disclosure. The computational operations 612 can be implemented using one or more databases 618, which store data received from the field operations 610 and/or generated internally within the computational operations 612 (e.g., by implementing the methods of the present disclosure) or both. For example, one or more computer systems 620 process inputs from the field operations 610 to assess conditions in the physical world, the outputs of which are stored in the databases 618. For example, seismic sensors of the field operations 610 can be used to perform a seismic survey to map subterranean features, such as facies and faults. In performing a seismic survey, seismic sources (e.g., seismic vibrators or explosions) generate seismic waves that propagate in the earth, and seismic receivers (e.g., geophones) measure reflections generated as the seismic waves interact with boundaries between layers of a subsurface formation. The source and received signals are provided to the computational operations 612 where they are stored in the databases 618 and analyzed by the one or more computer systems 620.

In some implementations, one or more outputs 622 generated by the one or more computer systems 620 can be provided as feedback/input to the field operations 610 (either as direct input or stored in the databases 618). The field operations 610 can use the feedback/input to control physical components used to perform the field operations 610 in the real world.

For example, the computational operations 612 can process the seismic data to generate three-dimensional (3D) maps of the subsurface formation. The computational operations 612 can use these 3D maps to provide plans for locating and drilling exploratory wells. In some operations, the exploratory wells are drilled using logging-while-drilling (LWD) techniques which incorporate logging tools into the drill string. LWD techniques can enable the computational operations 612 to process new information about the formation and control the drilling to adjust to the observed conditions in real-time.

The one or more computer systems 620 can update the 3D maps of the subsurface formation as information from one exploration well is received, and the computational operations 612 can adjust the location of the next exploration well based on the updated 3D maps. Similarly, the data received from production operations can be used by the computational operations 612 to control components of the production operations. For example, production well and pipeline data can be analyzed to predict slugging in pipelines leading to a refinery and the computational operations 612 can control the machine operated valves upstream of the refinery to reduce the likelihood of plant disruptions that run the risk of taking the plant offline.

In some implementations of the computational operations 612, customized user interfaces can present intermediate or final results of the above-described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or app), or at a central processing facility.

The presented information can include feedback, such as changes in parameters or processing inputs, that the user can select to improve a production environment, such as in the exploration, production, and/or testing of petrochemical processes or facilities. For example, the feedback can include parameters that, when selected by the user, can cause a change to, or an improvement in, drilling parameters (including drill bit speed and direction) or overall production of a gas or oil well. The feedback, when implemented by the user, can improve the speed and accuracy of calculations, streamline processes, improve models, and solve problems related to efficiency, performance, safety, reliability, costs, downtime, and the need for human interaction.

In some implementations, the feedback can be implemented in real-time, such as to provide an immediate or near-immediate change in operations or in a model. The term real-time (or similar terms as understood by one of ordinary skill in the art) means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second (s), or less than 5 s. While the requested data need not be displayed (or initiated for display) instantaneously, it is displayed (or initiated for display) without any intentional delay, taking into account processing limitations of a described computing system and the time required to, for example, gather, accurately measure, analyze, process, store, or transmit the data.

Events can include readings or measurements captured by downhole equipment such as sensors, pumps, bottom hole assemblies, or other equipment. The readings or measurements can be analyzed at the surface, such as by using applications that can include modeling applications and machine learning. The analysis can be used to generate changes to the settings of downhole equipment, such as drilling equipment. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart, or are located in different countries or other jurisdictions.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, nontransitory, computer-readable computer-storage medium for execution by, or to control the operation of, data processing apparatus. Alternatively, or additionally, the program instructions can be encoded in/on an artificially generated propagated signal. For example, the signal can be a machine-generated electrical, optical, or electromagnetic signal that is generated to encode information for transmission to a suitable receiver apparatus for execution by a data processing apparatus. The computer-storage medium can be a machine-readable storage device, a machine-readable storage substrate, a random or serial access memory device, or a combination of computer-storage mediums.

The term “real-time,” “real time,” “realtime,” “real (fast) time (RFT),” “near(ly) real-time (NRT),” “quasi real-time,” or similar terms (as understood by one of ordinary skill in the art), means that an action and a response are temporally proximate, such that an individual perceives the action and the response occurring substantially simultaneously. For example, the time difference for a response to display (or for an initiation of a display) of data following the individual's action to access and/or interact with the data can be less than 1 millisecond (ms), less than 1 second (s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

The terms “data processing apparatus,” “computer,” and “electronic computer device” (or equivalent as understood by one of ordinary skill in the art) refer to data processing hardware. For example, a data processing apparatus can encompass all kinds of apparatuses, devices, and machines for processing data, including by way of example, a programmable processor, a computer, or multiple processors or computers. The apparatus can also include special purpose logic circuitry, including, for example, a central processing unit (CPU), a field-programmable gate array (FPGA), or an application specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, such as LINUX, UNIX, WINDOWS, MAC OS, ANDROID, or IOS.

A computer program, which can also be referred to or described as a program, software, a software application, a module, a software module, a script, or code, can be written in any form of programming language. Programming languages can include, for example, compiled languages, interpreted languages, declarative languages, or procedural languages. Programs can be deployed in any form, including as standalone programs, modules, components, subroutines, or units for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files storing one or more modules, subprograms, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various embodiments and functionality through various objects, methods, or processes, the programs can instead include a number of sub-modules, third-party services, components, and libraries. Conversely, the embodiments and functionality of various components can be combined into single components as appropriate. Thresholds used to make computational determinations can be statically, dynamically, or both statically and dynamically determined.

The methods, processes, or logic flows described in this specification can be performed by one or more programmable computers, executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more general and special purpose microprocessors and other kinds of CPUs. The elements of a computer are a CPU for performing or executing instructions and one or more memory devices for storing instructions and data. Generally, a CPU can receive instructions and data from (and write data to) a memory.

Graphics processing units (GPUs) can also be used in combination with CPUs. The GPUs can provide specialized processing that occurs in parallel to the processing performed by CPUs. The specialized processing can include artificial intelligence (AI) applications and processing, for example. GPUs can be used in GPU clusters or in multi-GPU computing.

A computer can include, or be operatively coupled to, one or more mass storage devices for storing data. In some implementations, a computer can receive data from, and transfer data to, the mass storage devices including, for example, magnetic, magnetooptical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer readable-media (transitory or non-transitory, as appropriate) suitable for storing computer program instructions and data can include all forms of permanent/non-permanent and volatile/non-volatile memory, media, and memory devices. Computer readable-media can include, for example, semiconductor memory devices such as random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer readable-media can also include, for example, magnetic devices such as tape, cartridges, cassettes, and internal/removable disks. Computer readable-media can also include magneto-optical disks and optical memory devices and technologies including, for example, digital video disc (DVD), CD-ROM, DVD+/−R, DVD-RAM, DVD-ROM, HD-DVD, and BLU-RAY.

The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by or incorporated into special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), and a plasma monitor. Display devices can include a keyboard and pointing devices including, for example, a mouse, a trackball, or a trackpad. User input can also be provided to the computer through the use of a touchscreen, such as a tablet computer surface with pressure sensitivity, or a multi-touch screen using capacitive or electric sensing. Other kinds of devices can be used to provide interaction with a user, including to receive user feedback, and other feedback including, visual feedback, auditory feedback, or tactile feedback. Input from the user can be received in the form of acoustic, speech, or tactile input. In addition, a computer can interact with a user by sending documents to and receiving documents from, a device that the user uses. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch-screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, such as, a data server, or a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11a/b/g/n or 802.20 or a combination of protocols), all or a portion of the Internet, or any other communication system or systems at one or more locations (or a combination of communication networks). The network can communicate with, for example. Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship between client and server can arise by virtue of computer programs running on the respective computers and having a client-server relationship.

Cluster file systems can be any file system type accessible from multiple servers for reading and updating. Locking or consistency tracking may not be necessary since the locking of the exchange file system can be done at the application layer. Furthermore, Unicode data files can be different from non-Unicode data files.

While this specification contains many specific implementation details, these should not be construed as limitations on the scope of what may be claimed, but rather as descriptions of embodiments that may be specific to particular implementations. Certain embodiments that are described in this specification in the context of separate implementations can also be implemented, in combination, or in a single implementation. Conversely, various embodiments that are described in the context of a single implementation can also be implemented in multiple implementations, separately, or in any suitable sub-combination. Moreover, although previously described embodiments may be described as acting in certain combinations and even initially claimed as such, one or more embodiments from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims, as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations. It should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system including a computer memory interoperably coupled with a hardware processor configured to perform the computer-implemented method, or the instructions stored on the non-transitory, computer-readable medium.

### EMBODIMENTS

Described implementations of the subject matter can include one or more embodiments, alone or in combination.

For example, in a first aspect, a computer-implemented method includes the following. Data preprocessing is performed on core data and wireline data received from wells that have been drilled. The data processing generates pre-processed core and wireline data. The pre-processed core and wireline data are split into a training dataset and at least one testing dataset. A model is generated using the pre-processed core and wireline data. The model learns relationships between core-based depositional settings and wireline logs for the wells. Feature engineering is performed on the pre-processed core and wireline data to identify significant features of the pre-processed core and wireline data that contribute to the model. The model is trained using the training dataset and by weighting the significant features. The model is evaluated using machine learning on the testing dataset, depositional settings are predicted using the model and results of the evaluating.

The foregoing and other described implementations can each, optionally, include one or more of the following embodiments:

In a first embodiment, combinable with any of the previous or following embodiments, where performing the data preprocessing on the core data and wireline data includes labeling core interpretations, cleaning the core data and wireline data, removing data inconsistencies, and resolving missing data.

In a second embodiment, combinable with any of the previous or following embodiments, where splitting the pre-processed core and wireline data into a training dataset and at least one testing dataset includes splitting the pre-processed core and wireline data into a training set of 42% of cores data, a first testing set of 28% of the cores data, and a second testing set of 30% of the cores data.

In a third embodiment, combinable with any of the previous or following embodiments, where performing feature engineering on the pre-processed core and wireline data to identify significant features includes using machine learning with the model to identify respective contributions of different features for making predictions of depositional environments using the model.

In a fourth embodiment, combinable with any of the previous or following embodiments, where the respective contributions are represented as predictor weights weighting the significant features.

In a fifth embodiment, combinable with any of the previous or following embodiments, where the method further includes generating, using the predicted depositional environments and for display to a user, a depth chart showing model prediction and validation results.

In a sixth embodiment, combinable with any of the previous or following embodiments, where the depth chart includes, for each depth of a well, ML-predicted facies.

In a seventh embodiment, combinable with any of the previous or following embodiments, where training the model includes using the training dataset, weighting the significant features, and performing a sensitivity analysis that determines how accuracy of the model is affected by removal of input features.

In an eighth embodiment, combinable with any of the previous or following embodiments, further including selecting, based at least on the predicted depositional environments, data acquisition intervals including at least sampling, testing, perforation intervals, pressure points, and side well cores.

In a second aspect, a non-transitory, computer-readable medium stores one or more instructions executable by a computer system to perform operations including the following. Data preprocessing is performed on core data and wireline data received from wells that have been drilled. The data processing generates pre-processed core and wireline data. The pre-processed core and wireline data are split into a training dataset and at least one testing dataset. A model is generated using the pre-processed core and wireline data. The model learns relationships between core-based depositional settings and wireline logs for the wells. Feature engineering is performed on the pre-processed core and wireline data to identify significant features of the pre-processed core and wireline data that contribute to the model. The model is trained using the training dataset and by weighting the significant features. The model is evaluated using machine learning on the testing dataset, depositional settings are predicted using the model and results of the evaluating.

The foregoing and other described implementations can each, optionally, include one or more of the following embodiments:

In a first embodiment, combinable with any of the previous or following embodiments, where performing the data preprocessing on the core data and wireline data includes labeling core interpretations, cleaning the core data and wireline data, removing data inconsistencies, and resolving missing data.

In a second embodiment, combinable with any of the previous or following embodiments, where splitting the pre-processed core and wireline data into a training dataset and at least one testing dataset includes splitting the pre-processed core and wireline data into a training set of 42% of cores data, a first testing set of 28% of the cores data, and a second testing set of 30% of the cores data.

In a third embodiment, combinable with any of the previous or following embodiments, where performing feature engineering on the pre-processed core and wireline data to identify significant features includes using machine learning with the model to identify respective contributions of different features for making predictions of depositional environments using the model.

In a fourth embodiment, combinable with any of the previous or following embodiments, where the respective contributions are represented as predictor weights weighting the significant features.

In a fifth embodiment, combinable with any of the previous or following embodiments, where the operations further include generating, using the predicted depositional environments and for display to a user, a depth chart showing model prediction and validation results.

In a third aspect, a computer-implemented system includes one or more processors and a non-transitory computer-readable storage medium coupled to the one or more processors and storing programming instructions for execution by the one or more processors. The programming instructions instruct the one or more processors to perform operations including the following. Data preprocessing is performed on core data and wireline data received from wells that have been drilled. The data processing generates pre-processed core and wireline data. The pre-processed core and wireline data are split into a training dataset and at least one testing dataset. A model is generated using the pre-processed core and wireline data. The model learns relationships between core-based depositional settings and wireline logs for the wells. Feature engineering is performed on the pre-processed core and wireline data to identify significant features of the pre-processed core and wireline data that contribute to the model. The model is trained using the training dataset and by weighting the significant features. The model is evaluated using machine learning on the testing dataset, depositional settings are predicted using the model and results of the evaluating.

The foregoing and other described implementations can each, optionally, include one or more of the following embodiments:

In a first embodiment, combinable with any of the previous or following embodiments, where performing the data preprocessing on the core data and wireline data includes labeling core interpretations, cleaning the core data and wireline data, removing data inconsistencies, and resolving missing data.

In a second embodiment, combinable with any of the previous or following embodiments, where splitting the pre-processed core and wireline data into a training dataset and at least one testing dataset includes splitting the pre-processed core and wireline data into a training set of 42% of cores data, a first testing set of 28% of the cores data, and a second testing set of 30% of the cores data.

In a third embodiment, combinable with any of the previous or following embodiments, where performing feature engineering on the pre-processed core and wireline data to identify significant features includes using machine learning with the model to identify respective contributions of different features for making predictions of depositional environments using the model.

In a fourth embodiment, combinable with any of the previous or following embodiments, where the respective contributions are represented as predictor weights weighting the significant features.

What is claimed is:

1. A computer-implemented method, comprising:
performing, to generate pre-processed core and wireline data, data preprocessing on core data and wireline data received from wells that have been drilled;
splitting the pre-processed core and wireline data into a training dataset and at least one testing dataset;
generating, using the pre-processed core and wireline data, a model that models relationships between core-based depositional environments and wireline logs for the wells, comprising:
performing feature engineering on the pre-processed core and wireline data to identify significant features of the pre-processed core and wireline data that contribute to the model;
training, using the training dataset and weighting the significant features, the model; and
evaluating, using machine learning on the testing dataset, the model; and
predicting, as predicted depositional environments and using the model and results of the evaluating, depositional environments for a well.

2. The computer-implemented method of claim 1, wherein performing the data preprocessing on the core data and wireline data includes labeling core interpretations, cleaning the core data and wireline data, removing data inconsistencies, and resolving missing data.

3. The computer-implemented method of claim 1, wherein splitting the pre-processed core and wireline data into a training dataset and at least one testing dataset includes splitting the pre-processed core and wireline data into a training set of 42% of cores data, a first testing set of 28% of the cores data, and a second testing set of 30% of the cores data.

4. The computer-implemented method of claim 1, wherein performing feature engineering on the pre-processed core and wireline data to identify significant features includes using machine learning with the model to identify, respective contributions of different features for making predictions of depositional environments using the model.

5. The computer-implemented method of claim 4, wherein the respective contributions are represented as predictor weights weighting the significant features.

6. The computer-implemented method of claim 5, further comprising:
generating, using the predicted depositional environments and for display to a user, a depth chart showing model prediction and validation results.

7. The computer-implemented method of claim 6, wherein the depth chart includes, for each depth of a well, ML-predicted facies.

8. The computer-implemented method of claim 1, wherein training the model includes using the training dataset, weighting the significant features, and performing a sensitivity analysis that determines how accuracy of the model is affected by removal of input features.

9. The computer-implemented method of claim 1, further comprising selecting, based at least on the predicted depositional environments, data acquisition intervals including at least sampling, testing, perforation intervals, pressure points, and side well cores.

10. Anon-transitory, computer-readable medium storing one or more instructions executable by a computer system to perform operations comprising:
performing, to generate pre-processed core and wireline data, data preprocessing on core data and wireline data received from wells that have been drilled;
splitting the pre-processed core and wireline data into a training dataset and at least one testing dataset;
generating, using the pre-processed core and wireline data, a model that models relationships between core-based depositional environments and wireline logs for the wells, comprising:
performing feature engineering on the pre-processed core and wireline data to identify significant features of the pre-processed core and wireline data that contribute to the model;
training, using the training dataset and weighting the significant features, the model; and
evaluating, using machine learning on the testing dataset, the model; and
predicting, as predicted depositional environments and using the model and results of the evaluating, depositional environments for a well.

11. The non-transitory, computer-readable medium of claim 10, wherein performing the data preprocessing on the core data and wireline data includes labeling core interpretations, cleaning the core data and wireline data, removing data inconsistencies, and resolving missing data.

12. The non-transitory, computer-readable medium of claim 10, wherein splitting the pre-processed core and wireline data into a training dataset and at least one testing dataset includes splitting the pre-processed core and wireline data into a training set of 42% of cores data, a first testing set of 28% of the cores data, and a second testing set of 30% of the cores data.

13. The non-transitory, computer-readable medium of claim 10, wherein performing feature engineering on the pre-processed core and wireline data to identify significant features includes using machine learning with the model to identify respective contributions of different features for making predictions of depositional environments using the model.

14. The non-transitory, computer-readable medium of claim 13, wherein the respective contributions are represented as predictor weights weighting the significant features.

15. The non-transitory, computer-readable medium of claim 14, the operations further comprising:
generating, using the predicted depositional environments and for display to a user, a depth chart showing model prediction and validation results.

16. A computer-implemented system, comprising:
one or more processors; and
a non-transitory computer-readable storage medium coupled to the one or more processors and storing programming instructions for execution by the one or more processors, the programming instructions instructing the one or more processors to perform operations comprising:
performing, to generate pre-processed core and wireline data, data preprocessing on core data and wireline data received from wells that have been drilled;
splitting the pre-processed core and wireline data into a training dataset and at least one testing dataset;
generating, using the pre-processed core and wireline data, a model that models relationships between core-based depositional environments and wireline logs for the wells, comprising:
performing feature engineering on the pre-processed core and wireline data to identify significant features of the pre-processed core and wireline data that contribute to the model;
training, using the training dataset and weighting the significant features, the model; and
evaluating, using machine learning on the testing dataset, the model; and
predicting, as predicted depositional environments and using the model and results of the evaluating, depositional environments for a well.

17. The computer-implemented system of claim 16, wherein performing the data preprocessing on the core data and wireline data includes labeling core interpretations, cleaning the core data and wireline data, removing data inconsistencies, and resolving missing data.

18. The computer-implemented system of claim 16, wherein splitting the pre-processed core and wireline data into a training dataset and at least one testing dataset includes splitting the pre-processed core and wireline data into a training set of 42% of cores data, a first testing set of 28% of the cores data, and a second testing set of 30% of the cores data.

19. The computer-implemented system of claim 16, wherein performing feature engineering on the pre-processed core and wireline data to identify significant features includes using machine learning with the model to identify respective contributions of different features for making predictions of depositional environments using the model.

20. The computer-implemented system of claim 19, wherein the respective contributions are represented as predictor weights weighting the significant features.
